(19) United States
(12) Patent Application Publication
(10) Pub. No.: US 2013/0288401 A1
(43) Pub. Date: Oct. 31, 2013

(54) METHOD FOR FABRICATING SEMICONDUCTOR DEVICE

(71) Applicant: Sumitomo Electric Device Innovations, Inc., (US)

(72) Inventor: Kazuaki Matsuura, Yokohama-shi (JP)

(73) Assignee: SUMITOMO ELECTRIC DEVICE INNOVATIONS, INC., Yokohama-shi (JP)

(21) Appl. No.: 13/872,347

(22) Filed: Apr. 29, 2013

(30) Foreign Application Priority Data
Apr. 27, 2012 (JP) 2012-103529

(51) Int. Cl. H01L 21/66

(52) U.S. Cl. CPC H01L 22/10
USPC 438/14

(57) ABSTRACT

A method for fabricating a semiconductor device includes: forming a first layer and a second layer in this order on a nitride semiconductor layer on a first main surface side of a substrate, the first and second layers having one of first and second arrangements, the first arrangement having the first layer of any of Au, V and Ta and the second layer of Ni, the second arrangement having the first layer of any of Ti, TiW, Al, W, Mo, Nb, Pt, Ta and V and the second layer of Au; forming a mask on a second main surface side of the substrate, the mask having an opening; applying an etching process to the substrate and the nitride semiconductor layer exposed in the opening of the mask; and determining an endpoint of the etching process by confirming elimination of the first layer in the opening of the mask.

### CROSS-REFERENCE TO RELATED APPLICATION

This application is based upon and claims the benefit of priority of the prior Japanese Patent Application No. 2012-103529 filed on Apr. 27, 2012, the entire contents of which are incorporated herein by reference.

### BACKGROUND

(i) Technical Field

The present invention relates to a method for fabricating a semiconductor device.

(ii) Related Art

Refinement of semiconductor devices demands improvements in the breakdown voltage and power density. As materials that meet such demands, there is considerable activity in the research of wideband gap semiconductors such as nitride semiconductors and silicon carbide. Particularly, nitride semiconductors have physical features of wide band gaps and direct transition type, and have additional features of large insulation breakdown voltage, large drift velocity, good thermal conductivity and good heterojunction characteristics. From these viewpoints, nitride semiconductors are used as power device capable of outputting high power at high frequencies.

The technique of dry etching is used for microfabrication in devices using such wideband gap semiconductors. For example, Japanese Patent Application Publication No. 2005-317684 discloses a dry etching method capable of suppressing damage in plasma etching of nitride semiconductors.

Since nitride semiconductors are physically and chemically stable, increased power is used to form an opening by etching. However, increase in power for etching causes large differences of etching rate in different positions on the wafer surface or those for different batches of processes. Thus, there is a difficulty in the management of the quantity of etching by the etching time. Therefore, it is considered to determine whether the opening is completely formed by visual judgment or electron microscope.

However, since gallium nitride and aluminum nitride, which are nitride semiconductors, are transparent semiconductors, it is very difficult to determine whether the formation of the opening is complete by visual judgment or electron microscope.

### SUMMARY

According to an aspect of the present invention, there is provided a method for fabricating a semiconductor device capable of easily determining whether etching of a nitride semiconductor is complete.

According to another aspect of the present invention, there is provided A method for fabricating a semiconductor device including: forming a first layer and a second layer in this order on a nitride semiconductor layer on a first main surface side of a substrate, the first and second layers having one of first and second arrangements, the first arrangement having the first layer of any of Au, V and Ta and the second layer of Ni, the second arrangement having the first layer of any of Ti, TiW, Al, W, Mo, Nb, Pt, Ta and V and the second layer of Au; forming a mask on a second main surface side of the substrate, the mask having an opening; applying an etching process to the substrate and the nitride semiconductor layer exposed in the opening of the mask; and determining an endpoint of the etching process by confirming elimination of the first layer in the opening of the mask.

### BRIEF DESCRIPTION OF THE DRAWINGS

FIG. 1A through 1D are cross-sectional views illustrating a method for fabricating a semiconductor device in accordance with a comparative example;

FIGS. 2A through 2D are cross-sectional views illustrating a method for fabricating a semiconductor device in accordance with a first embodiment;

FIGS. 3A through 3D are cross-sectional views illustrating a method for fabricating a semiconductor device in accordance with a second embodiment; and

FIGS. 4A through 4D are cross-sectional views illustrating a method for fabricating a semiconductor device in accordance with a third embodiment.

### DESCRIPTION OF EMBODIMENTS

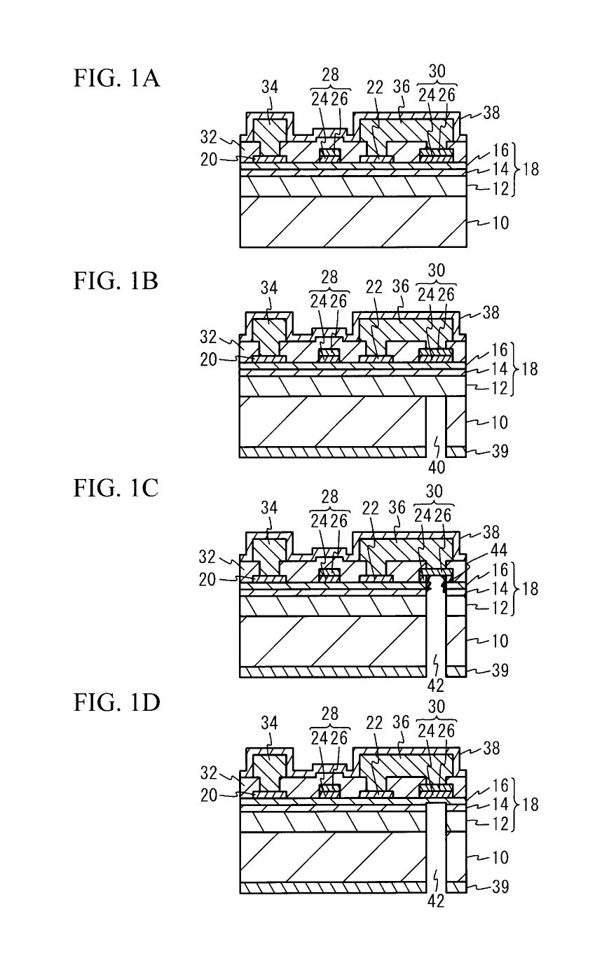

First, a description is given of a comparative example that is a HEMT (High Electron Mobility Transistor) using nitride semiconductors. FIGS. 1A through 1D are cross-sectional views illustrating a method for fabricating a HEMT of the comparative example. As illustrated in FIG. 1A, the method prepares a semiconductor device. This semiconductor device is manufactured by the following method.

A channel layer 12 of a GaN layer, an electron supply layer 14 of an AlGaN layer, and a cap layer 16 of a GaN layer are grown on an upper surface side (first main surface side) of a SiC substrate 10 in this order. These layers may be grown by MOCVD. As is well known, GaN and AlGaN have large band gap energies and are transparent to visible light (for example, 400 nm-700 nm). That is, visible light penetrates GaN and AlGaN. Thus, a transparent semiconductor layer 18 composed of nitride semiconductors is formed on the substrate 10.

A metal layer is formed by an evaporation method and a liftoff method in areas in which a drain electrode 20 and a source electrode 22 are to be formed. The metal layer is composed of a Ti layer and an Al layer stacked in this order from the cap layer 16. Then, the metal layer is annealed at a temperature of 500° C. to 800° C. to form the drain electrode 20 and the source electrode 22 that have ohmic contacts on the cap layer 16.

A gate electrode 28 is formed between the drain electrode 20 and the source electrode 22 by the evaporation method and the liftoff method. The gate electrode 28 is composed of a Ni layer 24 and an Au layer 26 stacked in this order from the cap layer 16. The gate electrode 28 has the Schottky barrier contact on the cap layer 16. When the gate electrode 28 is formed, a source pad 30 located closer to the chip end than the source electrode 22 is simultaneously formed. The source pad 30 is a metal layer composed of the Ni layer 24 and the Au layer 26 from the cap layer 16 as in the case of the gate electrode 28.

A first protection film 32 is grown by plasma CVD so as to cover the drain electrode 20, the gate electrode 28, the source electrode 22 and the source pad 30. The first protection film 32 may be a silicon nitride film.

Openings are formed by removing the first protection film 32 on the drain electrode 20, the source electrode 22 and the source pad 30. A seed layer (not illustrated) is formed in the openings and on the first protection film 32 by sputtering. Then a metal layer of Au is formed on the seed layer by electrolytic plating. The above process results in a drain interconnection line 34 that is electrically connected to the drain electrode 20, and a source interconnection line 36 that is electrically connected to the source electrode 22 and the source pad 30 and runs on the first protection film 32.

A second protection film 38 is formed by plasma CVD so as to cover the drain interconnection line 34 and the source interconnection line 36. The second protection film 38 may be a silicon nitride film.

Next, an opening for a backside interconnection line connected to the source pad 30 is formed in the semiconductor device illustrated in FIG. 1A. First, as illustrated in FIG. 1B, a first opening 40 is formed in the substrate 10 under the source pad 30 from the bottom side of the substrate 10 by etching the substrate 10 with a mask of a mask layer 39 having an opening formed on the lower surface side (second main surface side) of the substrate 10. The above etching may be dry etching such as RIE (Reactive Ion Etching) or ICP (Inductive Coupled Plasma) etching. Etching gas may be fluorine-based gas.

Since the substrate 10 is formed of SiC and is physically and chemically stable, dry etching is carried out by using increased power applied. Thus, there are very different etching rates in different positions on the wafer surface or those for different batches of processes. However, the channel layer 12 of GaN has a low etching rate in dry etching with fluorine-based gas. Further, it is desired to finally form the opening that pierces even the channel layer 12. Therefore, no problem occurs even when the channel layer 12 is etched. Thus, it is possible to manage the quantity of etching sufficient to complete removal of the substrate 10 by the etching time.

As illustrated in FIG. 1C, subsequent to the etching process to the substrate 10, etching is carried out for the transparent semiconductor layer 18 to change the first opening 40 into a second opening 42 that pierces the transparent semiconductor layer 18. This etching may be dry etching such as RIE or ICP etching as in the case of etching of the substrate 10. The channel layer 12 and the cap layer 16 of GaN layers, and the electron supply layer 14 of AlGaN are physically and chemically stable. Therefore, increased power for dry etching is applied. Therefore, there are very different etching rates in different positions on the wafer surface or those for different batches of processes.

In the etching process to the substrate 10, no problem occurs even when the channel layer 12 is etched. Thus, the quantity of etching may be managed by the etching time. However, in case where the transparent semiconductor layer 18 is excessively etched, up to the source pad 30 is etched, and an etching residue 44 of metal may occur in the second opening 42. In this case, the etching residue 44 may cause an etching fault such that the backside interconnection line is removed in the second opening 42.

As described above, it is difficult to manage the quantity of etching by the etching time. Therefore, it is considered to determine whether the process of etching the transparent semiconductor layer 18 is complete by use of visible light such as the visual judgment or microscope. However, the use of visible light has a difficulty in determining to what extent etching goes on because of transparency of the transparent semiconductor layer 18. In case where an erroneous determination is made by visible judgment or microscope and the quantity of etching is insufficient, as illustrated in FIG. 1D, the second opening 42 is not formed so as to pierce the transparent semiconductor layer 18, and the cap layer 16 or another layer remains. In this case, a connection fault occurs in which the backside interconnection line formed in the second opening 42 is not electrically connected to the source pad 30. Of course, excessive etching due to an erroneous determination made by visual judgment or microscope results in the etching residue 44 in the second opening 42, as illustrated in FIG. 1C.

Taking the above into consideration, embodiments described below are capable of easily determining whether the process of etching a nitride semiconductor layer composed of transparent semiconductor layers is complete.

### First Embodiment

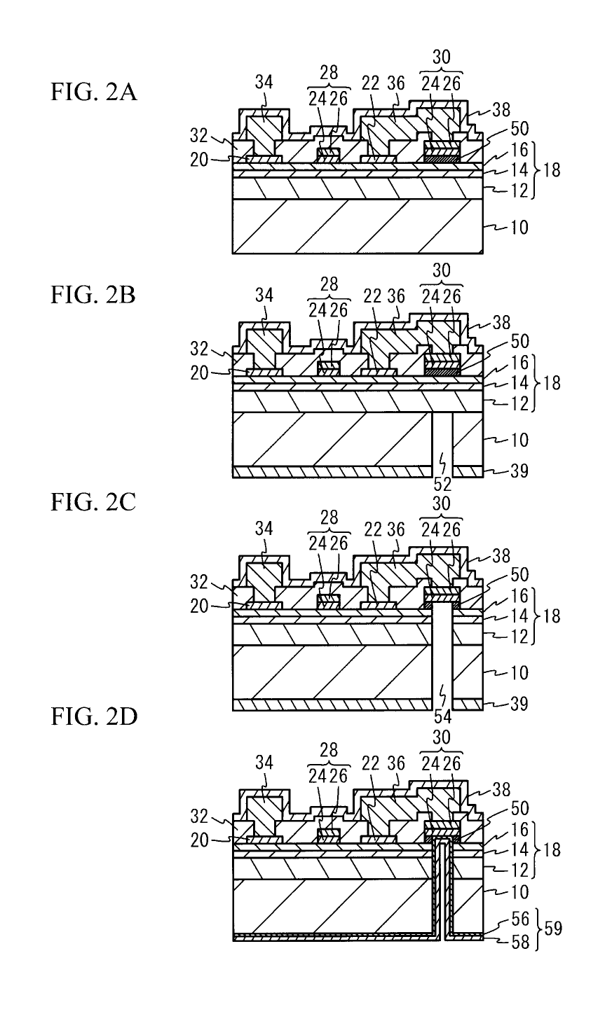

FIGS. 2A through 2D are cross-sectional views illustrating a method for fabricating a semiconductor device in accordance with a first embodiment. First, a semiconductor device illustrated in FIG. 2A is prepared. This semiconductor device may be formed by modifying the fabrication method of the comparative example previously described with reference to FIG. 1A. More particularly, a monitor layer 50 is formed in an area in which the source pad 30 is to be formed. The step of forming the monitor layer 50 is carried out after the drain electrode 20 and the source electrode 22 are formed and before the gate electrode 28 and the source pad 30 are formed. The monitor layer 50 may be a metal layer of Au having a thickness of 10 nm, for example. The monitor layer 50 may be formed by evaporation and liftoff. The monitor layer 50 is formed directly on the upper surface of the transparent semiconductor layer 18. The Ni layer 24 included in the source pad 30 is formed directly on the upper surface of the monitor layer 50.

Next, as illustrated in FIG. 2B, a first opening 52 that pierces the substrate 10 is formed in the substrate 10 under the source pad 30 from the bottom side of the substrate 10 by etching the substrate 10 with a mask of a mask layer 39 having an opening formed on the lower surface (second main surface) of the substrate 10. The substrate 10 may be 100 μm thick, for example. The first opening 52 may have an inner diameter of, for example, tens of microns to hundreds of microns. The width of the monitor layer 50 is larger than the inner diameter of the first opening 52, and may be 120 μm, for example. This etching may be dry etching such as RIE or ICP etching, for example. The etching gas may be fluorine-based gas.

As illustrated in FIG. 2C, subsequent to the process of etching the substrate 10, the transparent semiconductor layer 18 and the monitor layer 50 are subjected to etching to change the first opening 52 to a second opening 54 that pierces the transparent semiconductor layer 18 and the monitor layer 50. The second opening 54 is a via hole that makes a connection with the source pad 30. This etching may be dry etching such as RIE or ICP etching, for example, as in the case of etching the substrate 10. The etching gas may be chlorine-based gas. Increased power is applied in dry etching because the channel layer 12, the electron supply layer 14 and the cap layer 16 are physically and chemically stable. The following are exemplary etching conditions for RIE and those for ICP etching.

### 1. Etching Conditions for RIE

Etching gas and flow rate: Cl₂=1.0 sccm, or Cl₂/Ar=1.0/0.5-3.0 sccm
Pressure: 0.5-4.0 Pa
Rf power density: 1.0-4.0 W/cm²
Bias power density: 0.3-2.0 W/cm²

### 2. Conditions for ICP Etching

Etching gas and flow rate: Cl₂=1.0 sccm, or Cl₂/Ar=1.0/0.5-3.0 sccm
Pressure: 0.2-4.0 Pa
ICP power density: 1.0-4.0 W/cm²
Bias power density: 0.1-2.0 W/cm²

As has been described previously, dry etching with increased power causes large differences of etching rate in different positions on the wafer surface or those for different batches of processes. Thus, it is difficult to manage the quantity of etching by the etching time. Therefore, visible light such as visual judgment or microscope is used to determine whether the process of etching is complete. In this determination, the monitor layer 50 is provided between the transparent semiconductor layer 18 and the source pad 30. Therefore, the following determination may be made. When the color of gold is observed in the second opening 54 (that is, in the opening in the mask layer 39), it is determined that the monitor layer 50 of Au remains in the second opening 54 and the etching process is incomplete. As described above, if the monitor layer 50 is visually observed in the opening in the mask layer 39, etching is carried out again. In another case where the color of silver is observed in the area in the second opening 54 (that is, in the opening in the mask layer 39), the monitor layer 50 is removed and the Ni layer 24 is exposed. It is thus possible to make sure that the formation of the second opening 54 is complete, and the process of etching is thus complete. As described above, the color in the second opening 54 (that is, the opening in the mask layer 39) is used to easily determine whether the etching process is complete to form the second opening 54 that pierces the substrate 10, the transparent semiconductor layer 18 and the monitor layer 50. As described above, the endpoint of the etching process is determined by confirming elimination of the monitor layer 50 in the opening in the mask layer 39.

After it is determined that the process of etching the transparent semiconductor layer 18 and the monitor layer 50 is complete, as illustrated in FIG. 2D, a seed layer 56 made of Au is formed in the second opening 54 and the lower surface of the substrate 10 by sputtering. Thereafter, a metal layer 58 made of Au is formed on the lower and side surfaces of the seed layer 56 by electrolytic plating. Thus, a backside interconnection line 59 that is electrically connected to the source pad 30 is formed in the second opening 54 and the lower surface of the substrate 10. An electrode of the semiconductor device formed on the transparent semiconductor layer 18 that is the nitride semiconductor layer is extracted to the lower surface of the substrate 10 via the backside interconnection line 59.

According to the first embodiment, on the transparent semiconductor layer 18 that is the nitride semiconductor layer on the substrate 10, stacked are the monitor layer 50 (first layer) made of non-transparent Au, and the non-transparent Ni layer 24 (second layer) having a color different from that of the monitor layer 50 in that order. The mask layer 39 for selective etching having the opening is formed on the lower surface of the substrate 10, and the substrate 10 and the transparent semiconductor layer 18 exposed in the opening of the mask layer 39 are etched from the lower side of the substrate 10. In this etching, the exposure of the Ni layer 24 in the second opening 54 (that is, in the opening in the mask layer 39) is confirmed by visually making sure the color of the Ni layer 24 in order to determine whether the formation of the second opening 54 is complete and the etching process is thus complete. It is therefore to easily make sure that the formation of the second opening 54 that pierces the substrate 10, the transparent semiconductor layer 18 and the monitor layer 50 is complete and the etching process is thus complete. In case where the color of the Ni layer 24 is not confirmed but the monitor layer 50 is confirmed, the second opening 54 does not reach the Ni layer 24. In this case, etching is performed again to complete the second opening 54.

It is possible to make sure that the second opening 54 is completely formed to pierce the substrate 10, the transparent semiconductor layer 18 and the monitor layer 50. This makes it possible to form the backside interconnection line 59 electrically connected to the Ni layer 24 on the lower surface of the substrate 10, as illustrated in FIG. 2D. It is thus possible to suppress the occurrence of connection faults in which the backside interconnection line 59 is not electrically connected to the source pad 30. It is further possible to excessively etch the Ni layer 24 and suppress the occurrence of etching residues.

The monitor layer 50 has a thickness that makes it possible to recognize the color thereof. The thickness of the monitor layer 50 is preferably equal to or larger than 2 nm, more preferably equal to or larger than 5 nm, and is much more preferably equal to or larger than 10 nm. If the monitor layer 50 is excessively thick (for example, as equal as a thickness of 100 nm of the Ni layer 24), the etching residues that occur in etching of the monitor layer 50 are not negligible. Thus, the thickness of the monitor layer 50 is preferably equal to or smaller than 30 nm, more preferably equal to or smaller than 25 nm, and is much more preferably equal to smaller than 20 nm.

### Second Embodiment

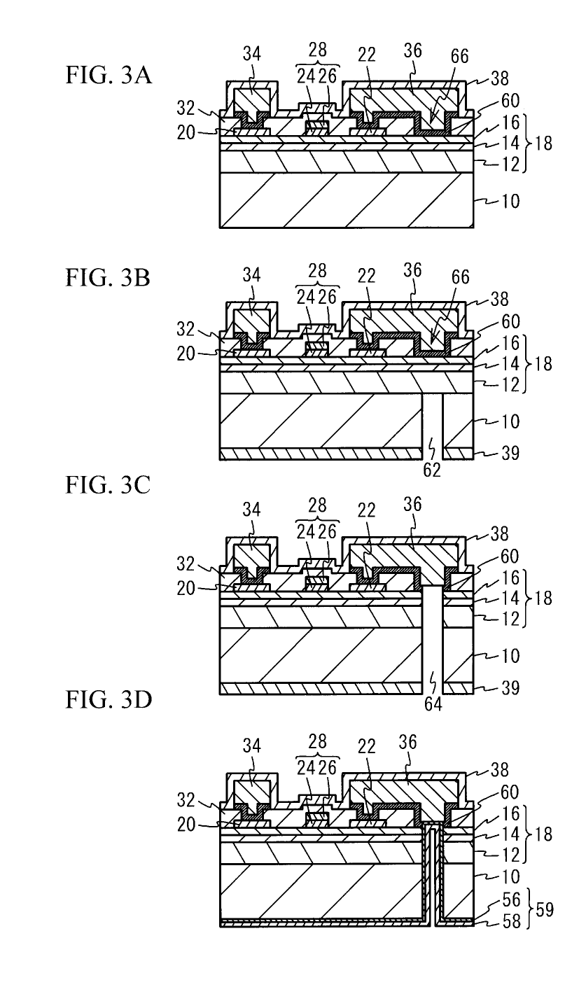

A second embodiment has an exemplary structure in which the monitor layer additionally functions as the seed layer used for forming the drain interconnection line 34 and the source interconnection line 36 by electrolytic plating. FIGS. 3A through 3D are cross-sectional views that illustrate a method for fabricating a semiconductor device in accordance with the second embodiment. First, a semiconductor device illustrated in FIG. 3A is prepared. The semiconductor device in FIG. 3A is fabricated in such a manner that the source pad 30 is not formed in the fabrication method of the comparative example illustrated in FIG. 1A but an opening 66 is formed by removing a portion of the first protection film 32 that is located closer to the chip end than the source electrode 22 at the same time as the opening is formed by removing the first protection film 32 on the drain electrode 20 and the source electrode 22. The monitor layer 60 made of Ti, TiW or Al is formed in the openings and on the first protection film 32 by sputtering. Then, a metal layer of Au is formed on the monitor layer 60 by electrolytic plating. The monitor layer 60 functions the seed layer by electrolytic plating, and additionally functions as the barrier layer that prevents the diffusion of Au. Further, the monitor layer 60 is made of a metal that may be Ti, TiW or Al, and is therefore a non-transparent layer.

Thus, the drain interconnection line 34 of Au is formed on the drain electrode 20 so as to contact the upper surface of the monitor layer 60. The source interconnection line 36 made of Au is formed on the source electrode 22 and in the opening 66 so as to contact the upper surface of the monitor layer 60. The monitor layer 60 in the opening 66 is formed in contact with the upper surface of the transparent semiconductor layer 18.

As illustrated in FIG. 3B, the substrate 10 is etched from its backside under the monitor layer 60 formed in the opening 66 with a mask of the mask layer 39 having the opening formed on the lower surface of the substrate 10. Thus, a first opening 62 that pierces the substrate 10 is formed. This etching process may be used as that used in the first embodiment.

As illustrated in FIG. 3C, subsequent to the etching process for the substrate 10, the transparent semiconductor layer 18 and the monitor layer 60 are etched to change the first opening 62 to a second opening 64, which pierces the monitor layer 60 as well as the transparent semiconductor layer 18. The etching process may be the same as that used in the first embodiment. The same manner as that used in the first embodiment may be used to determine whether the formation of the second opening 64 is complete and the etching process is thus complete. More specifically, when the color in the second opening 64 (that is, in the opening in the mask layer 39) is silver, it is determined that the monitor layer 60 made of Ti, TiW or Al remains and that the formation of the second opening 64 is incomplete and the etching process is therefore incomplete. When the color in the second opening 64 is gold, it is determined that the monitor layer 60 is completely removed and the source interconnection line 36 made of Au is exposed and that the formation of the second opening 64 is complete and the etching process is thus complete.

After the process of etching the transparent semiconductor layer 18 and the monitor layer 60 is complete, as illustrated in FIG. 3D, the seed layer 56 of Au is formed in the second opening 64 and on the lower surface of the substrate 10 by sputtering. Thereafter, a metal layer 58 of Au is formed on the lower and side surfaces of the seed layer 56 by electrolytic plating. Thus, the backside interconnection line 59 electrically connected to the source interconnection line 36 is formed in the second opening 64 and on the lower surface of the substrate 10.

In the second embodiment, the source interconnection line 36 is formed by electrolytic plating with the monitor layer (first layer) 60 being as the seed layer. Further, the non-transparent source interconnection line (second layer) 36 that has a color different from that of the monitor layer 60 is provided on the non-transparent monitor layer 60. Even in this case, it is determined whether the formation of the second opening 64 is complete and the etching process is thus complete by visually making sure the color of the source interconnection line 36 that is exposed in the second opening 64 (that is, in the opening of the mask layer 39). It is thus possible to easily make sure that the formation of the second opening 64 that pierces the substrate 10, the transparent semiconductor layer 18 and the monitor layer 60 is complete and the etching process is thus complete. Further, the second embodiment employs the monitor layer 60 that is also used as the seed layer, so that there is no need to separately form the monitor layer 60 and the seed layer. This advantage reduces the number of steps of the fabrication process. Further, it is possible to determine whether the formation of the second opening 64 is complete for each semiconductor device in the wafer.

The monitor layer 60 used in the second embodiment has a thickness sufficient to recognize its color. Therefore, the thickness of the monitor layer 60 is preferably equal to or larger than 2 nm, more preferably equal to or larger than 5 nm, and is much more preferably equal to or larger than 10 nm. An excessive thickness of the monitor layer 60 may cause a problem of the etching residues in the process of etching the monitor layer 60. From this viewpoint, the thickness of the monitor layer 60 is preferably equal to or smaller than 30 nm, more preferably equal to or smaller than 25 nm, and is much more preferably equal to or lower than 20 nm.

### Third Embodiment

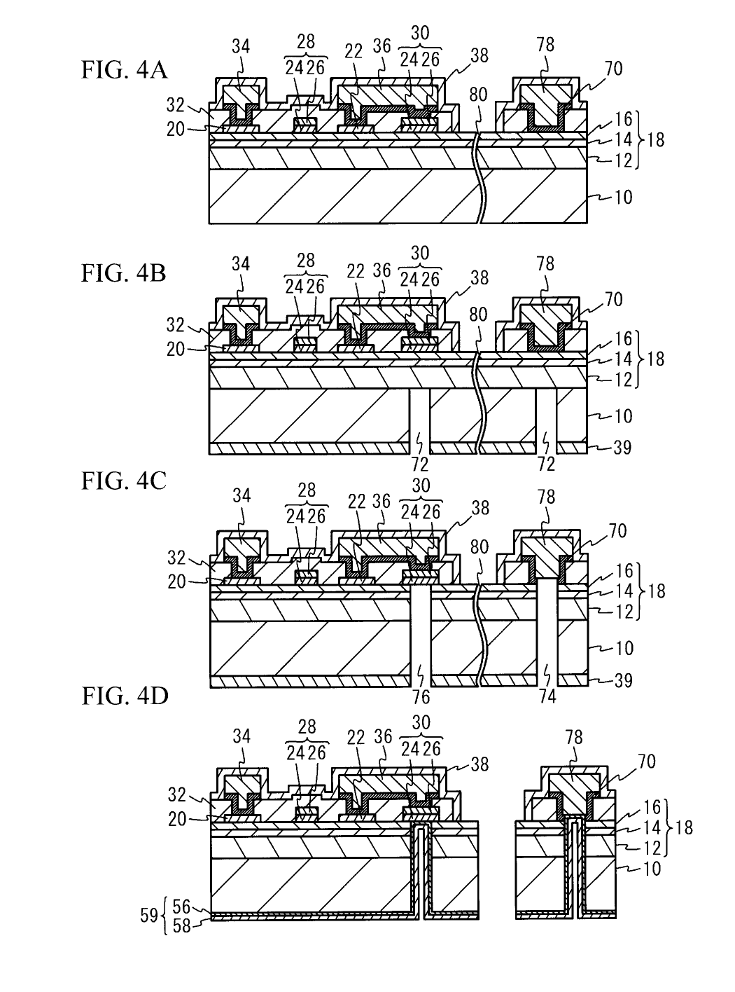

A third embodiment has an exemplary structure in which the monitor layer is formed in a position different from the position where the source pad 30 is formed. FIGS. 4A through 4D are cross-sectional views that illustrate a method for fabricating a semiconductor device in accordance with a third embodiment. First, a semiconductor device illustrated in FIG. 4A is prepared. This semiconductor device may be fabricated in such a manner that an opening is formed by removing a portion of the first protection film 32 located further out than a scribe line 80 at the same time as the openings are formed in the first protection film 32 on the drain electrode 20, the source electrode 22 and the source pad 30 in the fabrication method of the comparative example illustrated in FIG. 1A. A monitor layer 70 made of Ti, TiW or Al is formed in the openings and the first protection film 32 by sputtering. Then, a metal layer of Au is formed on the monitor layer 70 by electrolytic plating. The monitor layer 70 is a metal layer made of Ti, TiW or Al, and is non-transparent.

The drain interconnection line 34 made of Au is formed directly on the upper surface of the monitor layer 70 on the drain electrode 20. The source interconnection line 36 of Au is formed directly on the upper surface of the monitor layer 70 on the source electrode 22 and the source pad 30. A dummy interconnection line 78 made of Au is formed directly on the upper surface of the monitor layer 70 located further out than the scribe line 80. The monitor layer 70 below the dummy interconnection line 78 is formed directly on the upper surface of the transparent semiconductor layer 18.

As illustrated in FIG. 4B, the substrate 10 is etched from its backside by using a mask of the mask layer 39 having openings located below the source pad 30 and the dummy interconnection line 78 and formed on the lower surface of the substrate 10. This etching results in a first opening 72 that pierces the substrate 10. The etching process may be the same as that employed in the first embodiment described previously.

As illustrated in FIG. 4C, subsequent to the etching process for the substrate 10, the transparent semiconductor layer 18 and the monitor layer 70 are etched. This etching changes the first opening 72 below the dummy interconnection line 78 to a second opening 74, which pierces the substrate 10, the transparent semiconductor layer 18 and the monitor layer 70. The first opening 72 below the source pad 30 is changed to a third opening 76 that pierces the substrate 10 and the transparent semiconductor layer 18, in which the lower surface of the source pad 30 is exposed. The etching process may be the same as that employed in the first embodiment. The same manner as that employed in the first embodiment may be used to determine whether the formation of the second opening 74 and the third opening 76 is complete and to determine whether the etching process is thus complete. That is, when the color in the second opening 74 (that is, in the opening in the mask layer 39) is silver, it is determined that the monitor layer 70 of Ti, TiW or Al remains and that the formation of the second opening 74 and the third opening 76 are incomplete and the etching process is thus incomplete. In contrast, when the color in the second opening 74 is gold, it is determined that the monitor layer 70 is removed and the dummy interconnection line 78 of Au is exposed and that the formation of the second opening 74 and the third opening 76 are complete and the etching process is thus complete. When the formation of the second opening 74 is complete, the formation of the third opening 76 is definitely complete.

After it is determined that the process of etching the transparent semiconductor layer 18 and the monitor layer 70 is complete, as illustrated in FIG. 4D, the seed layer 56 of Au is formed in the third opening 76 and on the lower surface of the substrate 10 by sputtering. After that, the metal layer 58 of Au is formed on the lower and side surfaces of the seed layer 56 by electrolytic plating. Thus, the backside interconnection line 59 electrically connected to the source pad 30 is formed in the third opening 76 and on the lower surface of the substrate 10. Further, the backside interconnection line 59 electrically connected to the dummy interconnection line 78 is formed in the second opening 74. Then, the wafer is divided into individual chips along the scribe line 80. Thus, the portion of the dummy interconnection line 78 is separated from the chips.

The third embodiment has an exemplary structure in which the non-transparent monitor layer 70 (first layer) and the non-transparent dummy interconnection line 78 (second layer) having a color different from that of the monitor layer 70 are formed in positions different from that where the source pad 30 is formed. It is determined that the dummy interconnection line 78 is exposed in the second opening 74 (that is, the opening in the mask layer 39) by visually confirming the color of the dummy interconnection line 78. It is thus possible to determine that the formation of the second opening 74 is complete and the etching process is thus complete. It is thus possible to easily make sure the completion of the second opening 74 that pierces the substrate 10, the transparent semiconductor layer 18 and the monitor layer 70 and the completion of the third opening 76 that pierces the substrate 10 and the transparent semiconductor layer 18 and that the etching process is thus complete.

The monitor layer 70 (first layer) and the dummy interconnection line 78 (second layer) are formed in positions different from the position where the source pad 30 is formed. This arrangement avoids the use of an extra layer between the source pad 30 and the transparent semiconductor layer 18. It is thus possible to prevent the electric characteristics from being degraded by the use of such an extra layer.

The monitor layer 70 used in the third embodiment has a thickness sufficient to recognize its color. Therefore, the thickness of the monitor layer 70 is preferably equal to or larger than 2 nm, more preferably equal to or larger than 5 nm, and is much more preferably equal to or larger than 10 nm. An excessive thickness of the monitor layer 70 may cause a problem of the etching residues that occur because the Ni layer 24 in the third opening 76 is etched. From this viewpoint, the thickness of the monitor layer 70 is preferably equal to or smaller than 30 nm, more preferably equal to or smaller than 25 nm, and is much more preferably equal to or lower than 20 nm.

The first through third embodiments determine whether the color in the second opening 54, 64 or 74 is gold or silver in order to determine whether the formation of the second opening is complete and the etching process is thus complete. However, the present invention is not limited to the above. Another color may be used to determine whether the formation of the openings is complete and the etching process is thus complete. It is also possible to use lightness or saturation of color for the purpose of determining whether the openings are completed and etching is finished. That is, any of the three attributes of color may be used to visually check the openings. Therefore, the monitor layer (first layer) and the second layer formed thereon are different from each other in any of the three attributes of color. Particularly, as in the case of the first through third embodiments, the use of the color phase in the openings has high reliability. Therefore, it is preferable that the monitor layer (first layer) and the second layer formed thereof have different color phases.

In the first through third embodiments, the second openings 54, 64 and 74 are formed by subjecting the transparent semiconductor layer 18 and the monitor layers 50, 60 and 70 to etching with the common etching gas (chlorine-based gas). It is preferable that the monitor layers 50, 60 and 70 are etched with the same etching gas (chlorine-based gas) as that used in the process of etching the transparent semiconductor layer 18. Thus, the monitor layers 50, 60 and 70 are successively removed after the removal of the transparent semiconductor layer 18. It is therefore to easily determine whether the second openings 54, 64 and 74 are complete by checking the colors in the second openings 54, 64 and 74. Materials that are likely to be etched by chlorine-based gas may be materials having low boiling points in the form of chloride. Examples of such materials are Al, As, Au, C, Fe, Ga, Ge, Hg, Mo, Nb, P, Pt, Si, Ta, Ti and W, or alloys or compounds thereof. Thus, it is preferable that the monitor layers 50, 60 and 70 are formed by a material that is selected from the above and is different from the material of the second layers formed on the monitor layers 50, 60 and 70. For example, in a case where the second layer on the monitor layer 50 is made of Ni as in the case of the first embodiment, the monitor layer 50 is preferably made of Au, V or Ta. In a case where the second layers on the monitor layers 60 and 70 are made of Au as in the case of the second and third embodiments, it is preferable that the monitor layers 60 and 70 are made of any of Ti, TiW and Al, or are made of any of W, Mo, Nb, Pt, Ta and V.

The monitor layers 50, 60 and 70 may be made of a metal or a non-metal. For the structures of the first and second embodiments, a metal is preferably used for the monitor layers 50 and 60. This is because, even if only a thin layer of the monitor layer 50 or 60 remains in the process of etching the transparent semiconductor layer 18 and the monitor layer 50 or 60, the backside interconnection line 59 formed later can be electrically connected to the source interconnection line 36.

In the first through third embodiments, the substrate 10 may be a non-transparent substrate instead of the transparent substrate. Therefore, the substrate 10 is not limited to the SiC substrate but may be another substrate of GaN, Si, GaAs or sapphire. The transparent semiconductor layer 18 may be nitride semiconductors other than GaN and AlGaN. Examples of those nitride semiconductors are AlN, InN, InGaN, InAlN and InAlGaN.

The present invention includes not only HEMTs but also other types of FETs (Field Effect Transistors). For example, the present invention includes MESFET (Metal Semiconductor Field Effect Transistor). The present invention includes semiconductor devices other than FETs.

The present invention is not limited to the above-described structures of the first through third embodiments in which the transparent semiconductors are provided on the substrate, but includes another structure in which a transparent semiconductor itself has the function of the substrate. The transparent semiconductor is not limited to the nitride semiconductors but is a semiconductor transparent to the visible light such as SiC. The second layer formed on the monitor layer (first layer) is not limited to Au but may be made of a non-metal.

The present invention is not limited to the specifically described embodiments, but may include other embodiments and variations without departing from the scope of the present invention.

What is claimed is:

1. A method for fabricating a semiconductor device comprising:
forming a first layer and a second layer in this order on a nitride semiconductor layer on a first main surface side of a substrate, the first and second layers having one of first and second arrangements,
the first arrangement having the first layer of any of Au, V and Ta and the second layer of Ni,
the second arrangement having the first layer of any of Ti, TiW, Al, W, Mo, Nb, Pt, Ta and V and the second layer of Au;
forming a mask on a second main surface side of the substrate, the mask having an opening;
applying an etching process to the substrate and the nitride semiconductor layer exposed in the opening of the mask; and
determining an endpoint of the etching process by confirming elimination of the first layer in the opening of the mask.

2. The method according to claim 1, wherein the first layer has a thickness that is equal to or larger than 2 nm and is equal to or smaller than 30 nm.

3. The method according to claim 1, wherein the determining uses visible light.

4. The method according to claim 1, wherein the etching is further carried out in a case where the first layer is confirmed in the opening of the mask in the determining

5. The method according to claim 1, further comprising forming, on the second main surface side of the substrate, a metal layer electrically connected to the second layer after it is determined that the etching is complete.

6. The method according to claim 5, wherein the nitride semiconductor layer includes a semiconductor device, and an electrode is extended to the second main surface side of the substrate via the metal layer electrically connected to the second layer.

7. The method according to claim 1, further comprising forming the second layer by a plating method with the first layer being used as a seed layer.

8. The method according to claim 1, wherein the etching process is executed by an RIE method or an ICP method.

9. The method according to claim 1, wherein the nitride semiconductor layer and the first layer are etched with a chlorine-based gas in the etching process.
